(19) United States
(12) Patent Application Publication
(10) Pub. No.: US 2016/0217727 A1
(43) Pub. Date: Jul. 28, 2016

(54) DISPLAY PANEL AND DRIVING METHOD THEREOF AS WELL AS DISPLAY DEVICE

(71) Applicants: BOE TECHNOLOGY GROUP CO., LTD., Beijing (CN); Beijing Boe Display Technology Co., Ltd., Beijing (CN)

(72) Inventors: Huibin Guo, Beijing (CN); Liangliang Li, Beijing (CN); Shoukun Wang, Beijing (CN); Yuchun Feng, Beijing (CN); Jing Wang, Beijing (CN); Zongjie Guo, Beijing (CN); Jianfeng Yuan, Beijing (CN)

(21) Appl. No.: 14/803,876

(22) Filed: Jul. 20, 2015

(30) Foreign Application Priority Data
Jan. 23, 2015 (CN) 201510033726.X

(51) Int. Cl. G09G 3/20; G11C 19/18

(52) U.S. Cl. CPC G09G 3/2092; G11C 19/184; G11C 19/188; G09G 2310/0286; G09G 2310/0248

(57) ABSTRACT

The embodiment of the present invention discloses a display panel, a driving method thereof and a display device, a plurality of shift register units connected in one-to-one correspondence are arranged at one terminal of a plurality of gate lines, a plurality of charging modules connected in one-to-one correspondence are arranged at the other terminal of the plurality of gate lines; each charging module charges a corresponding gate line when the corresponding gate line is applied with a scanning signal by the shift register unit, i.e., when the shift register unit applies a scanning signal to the gate line, the charging module to which the gate line corresponds charges the gate line at the same time, which realizes bidirectional application of the scanning signal to the gate line, and increases the charging rate of the gate line.

### RELATED APPLICATIONS

The present application claims the benefit of Chinese Patent Application No. 201510033726.X, filed on Jan. 23, 2015, the entire disclosure of which is incorporated herein by reference.

### FIELD OF THE INVENTION

The present invention relates to the field of display technology, particularly to a display panel, a driving method thereof and a display device.

### BACKGROUND OF THE INVENTION

At present, the display technology has been widely used in display of television, mobile phone and common information, there are also various display panels for displaying images. Moreover, rich and colorful images can be displayed. However, both the thin film transistor-liquid crystal display (TFT-LCD) panel and the organic light emitting diode (OLED) display panel need control of a driving integrated circuit (IC). The driving IC controls the display panel to implement the functions of line by line scanning and frame by frame refreshing so that the image data inputted into the display panel can be refreshed in real time, thereby realizing dynamic display. The gate driving IC is responsible for realizing line by line scanning, and generating gate line scanning signals opened line by line with respect to time sequence control. Each row of gate line scanning signal is applied to the corresponding gate line to turn on the switch for controlling the pixels, so that the image data enters the storage capacitance of this row of pixels, and finally realizing normal display of images.

With the development of the panel display technology, the skilled person in the related technical field begins to make use of the edge of the display panel to build the gate integrated driving circuit, wherein the gate integrated driving circuit comprises a plurality of cascaded shift register units. Scanning signals are outputted to the corresponding gate lines through the respective shift register units, so as to implement the function of gate driving IC. Such a design can avoid the setting of a gate driving IC separately at the frame area of the display panel, which is favorable for realizing narrow frame design of the display panel and reducing the production cost of the related product at the same time. However, the contradiction between the size and the charging rate of the gate integrated driving circuit emerges gradually. In the prior art, in order to increase the charging rate of the gate integrated driving circuit to the gate line, the areas occupied by the respective shift register units in the gate integrated driving circuit have to be expanded, or the bilaterally arranged gate integrated driving circuit is used for bilateral driving, whereas arranging the gate integrated driving circuit bilaterally or setting a relatively large area of the shift register units in the gate integrated driving circuit would occupy the frame of the display panel, which is unfavorable for the narrow frame design.

Therefore, increasing the charging rate to respective rows of gate lines while ensuring narrow frame design of the display panel is a problem that needs to be urgently solved by the skilled person in the art.

### SUMMARY OF THE INVENTION

The embodiments of the present invention provide a display panel, a driving method thereof and a display device, for solving the problem of failing to increase the charging rate of respective gate lines effectively while keeping narrow frame design of the display panel existing in the prior art.

The embodiment of the present invention provides a display panel, comprising: a plurality of gate lines, and a plurality of shift register units connected with one terminal of the plurality of gate lines respectively in one-to-one correspondence, the display panel further comprises a plurality of charging modules connected with the other terminal of the plurality of gate lines respectively in one-to-one correspondence, a control terminal and an output terminal of each charging module are connected with a corresponding gate line respectively, an input terminal of each charging module is connected with a signal input line;

each charging module is used for charging a gate line connected by the output terminal of the charging module when the gate line connected by the control terminal of the charging module is applied with a scanning signal by the shift register unit.

In a possible implementing mode, in the above display panel provided by the embodiment of the present invention, the charging module comprises a first switch transistor;

a gate and a drain of the first switch transistor are connected with the gate line respectively, a source of the first switch transistor is connected with the signal input line.

In a possible implementing mode, the above display panel provided by the embodiment of the present invention, further comprises a plurality of discharging modules connected with the other terminal of the gate lines except for the first row of gate line in the plurality of gate lines respectively in one-to-one correspondence;

a control terminal of each discharging module is connected with a corresponding gate line, an input terminal of each discharging module is connected with a low level signal line, an output terminal of each discharging module is connected with a previous row of gate line adjacent to the corresponding gate line;

each discharging module is used for discharging a gate line connected by the output terminal of the discharging module when the gate line connected by the control terminal of the discharging module is applied with a scanning signal by the shift register unit.

In a possible implementing mode, in the above display panel provided by the embodiment of the present invention, the discharging module comprises a second switch transistor;

a gate of the second switch transistor is connected with a corresponding gate line, a source of the second switch transistor is connected with the low level signal line, a drain of the second switch transistor is connected with a previous row of gate line adjacent to the corresponding gate line.

In a possible implementing mode, in the above display panel provided by the embodiment of the present invention, the number of the signal input line is one, and the signal inputted by the signal input line is a DC signal.

In a possible implementing mode, in the above display panel provided by the embodiment of the present invention, the number of the signal input lines is two, and signals inputted by the two signal input lines have opposite polarities at the same moment;

any two adjacent charging modules in the plurality of charging modules are connected with different signal input lines respectively.

In a possible implementing mode, in the above display panel provided by the embodiment of the present invention, each shift register unit has two signal input terminals, signals inputted by the two signal input terminals are the same as the signals inputted by the two signal input lines respectively.

The embodiment of the present invention provides a method of driving the above display panel, comprising:

the plurality of shift register units applying a scanning signal to the correspondingly connected plurality of gate lines successively;

when each gate line is applied with a scanning signal, the charging module connected with the gate line charging the gate line.

In a possible implementing mode, the method of driving the above display panel provided by the embodiment of the present invention further comprises:

when each gate line in the plurality of gate lines except for the first row of gate line is applied with a scanning signal, the discharging module connected with the gate line discharging a previous row of gate line adjacent to the gate line.

The embodiment of the present invention provides a display device comprising the above display panel provided by the embodiment of the present invention.

The beneficial effects of the embodiments of the present invention include:

The embodiment of the present invention provides a display panel, a driving method thereof and a display device, the display panel comprising a plurality of gate lines, and a plurality of shift register units connected with one terminal of the plurality of gate lines respectively in one-to-one correspondence, further comprising a plurality of charging modules connected with the other terminal of the plurality of gate lines respectively in one-to-one correspondence; a control terminal and an output terminal of each charging module are connected with a corresponding gate line respectively, an input terminal of each charging module is connected with a signal input line; each charging module is used for charging a gate line connected by the output terminal of the charging module when the gate line connected by the control terminal of the charging module is applied with a scanning signal by the shift register unit. In this way, shift register units in one-to-one correspondence with the gate lines are arranged at one terminal of the gate lines in the display panel, meanwhile charging modules in one-to-one correspondence with the gate lines are arranged at the other terminal of the gate lines, when the shift register unit applies a scanning signal to the gate line, the charging module to which the gate line corresponds charges the gate line at the same time, i.e., the gate line is also applied with the scanning signal, thereby the gate line can be applied with the scanning signal bidirectionally, which increases the charging rate of the gate line. Compared with the manner of expanding the areas occupied by respective shift register units or using the bilaterally arranged gate integrated driving circuit for bilateral driving in order to increase the charging rate of the gate line in the prior art, the display panel provided by the embodiment of the present invention only uses the unilaterally arranged gate integrated driving circuit, and the areas occupied by the respective shift register units in the gate integrated driving circuit do not have to be expanded, which ensures narrow frame design of the display panel, thereby increasing the charging rate of the gate line while keeping narrow frame design of the display panel.

### BRIEF DESCRIPTION OF DRAWINGS

FIG. 1 is a first structural schematic view of a display panel provided by an embodiment of the present invention.

FIG. 2 is a second structural schematic view of a display panel provided by an embodiment of the present invention.

FIG. 3 is a first structural schematic view of a charging module and a discharging module provided by an embodiment of the present invention.

FIG. 4 is a second structural schematic view of a charging module and a discharging module provided by an embodiment of the present invention.

FIG. 5 is a third structural schematic view of a display panel provided by an embodiment of the present invention.

FIG. 6 is a flow chart of a method of driving a display panel provided by an embodiment of the present invention.

### DETAILED DESCRIPTION OF THE INVENTION

Next, the specific implementing modes of the display panel, the driving method thereof and the display device provided by the embodiments of the present invention will be explained in detailed with reference to the drawings.

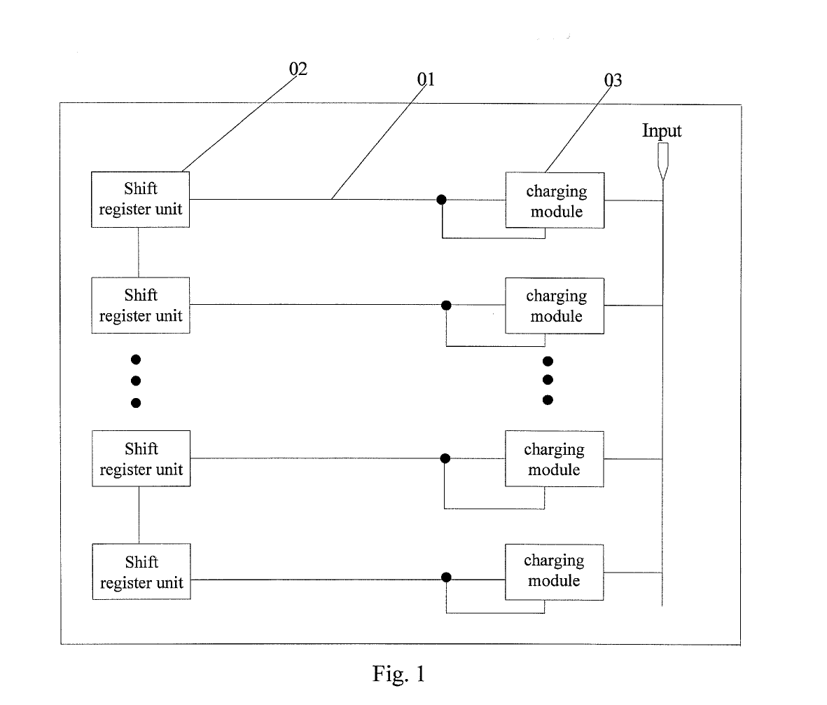

The embodiment of the present invention provides a display panel, as shown in FIG. 1, comprising: a plurality of gate lines 01, and a plurality of shift register units 02 connected with one terminal of the plurality of gate lines 01 respectively in one-to-one correspondence. The display panel further comprises: a plurality of charging modules 03 connected with the other terminal of the plurality of gate lines 01 respectively in one-to-one correspondence; a control terminal and an output terminal of each charging module 03 are connected with a corresponding gate line respectively, and an input terminal of each charging module is connected with a signal input line Input.

Each charging module 03 is used for charging a gate line 01 connected by the output terminal of the charging module when the gate line 01 connected by the control terminal of the charging module is applied with a scanning signal by the shift register unit 02.

In the above display panel, the shift register units 02 connected with the respective gate lines 01 in one-to-one correspondence are arranged at one terminal of the respective gate lines 01. The charging modules 03 connected with the respective gate lines 01 in one-to-one correspondence are arranged at the other terminal of the respective gate lines 01. When the shift register unit 02 applies a scanning signal to the gate line 01, the charging module 03 to which the gate line 01 corresponds charges the gate line 01 at the same time, i.e., the charging module 03 to which the gate line 01 corresponds also applies a scanning signal to the gate line 01, thereby the gate line 01 can be applied with the scanning signal bidirectionally, which increases the charging rate of the gate line 01. Compared with the manner of expanding the areas occupied by respective shift register units or using bilaterally arranged gate integrated driving circuit for bilateral driving in order to increase the charging rate of the gate line in the prior art, the display panel provided by the embodiment of the present invention only uses unilaterally arranged gate integrated driving circuit. The areas occupied by the respective shift register units in the gate integrated driving circuit do not have to be expanded, which ensures narrow frame design of the display panel, thereby increasing the charging rate of the gate line while keeping narrow frame design of the display panel.

Specifically, when the unilaterally arranged gate integrated driving circuit is used for driving the display panel in the prior art, in order to increase the load capacity of the gate line, the gate line is generally set to be relatively thick, thus the resistance of the gate line will be relatively small. However, the aperture ratio will be decreased correspondingly. Although the display panel provided by the embodiment of the present invention uses the manner of arranging the gate integrated driving circuit unilaterally, bidirectional application of the scanning signal to the gate line can be achieved since the charging modules in one-to-one correspondence are arranged at the other terminal of the gate line. Therefore, the charging rate of the gate line can be increased while there is no need to increase the load capacity of the gate line, thus the gate line can be set relatively thin, so as to increase the charging rate of the gate line in the case of not influencing the aperture ratio.

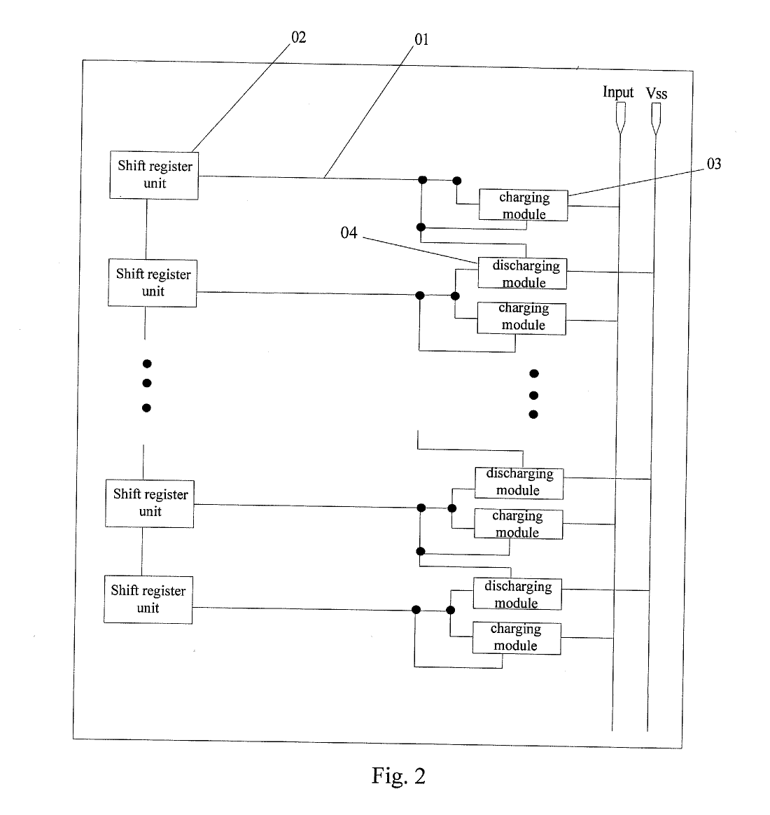

In specific implementation, the above display panel provided by the embodiment of the present invention, as shown in FIG. 2, may further comprise: a plurality of discharging modules 04 connected with the other terminal of the gate lines except for the first row of gate line in the plurality of gate lines 01 respectively in one-to-one correspondence; and a control terminal of each discharging module 04 connected with a corresponding gate line 01, an input terminal of each discharging module 04 connected with a low level signal line Vss, an output terminal of each discharging module 04 connected with a previous row of gate line adjacent to the corresponding gate line. Each discharging module 04 is used for discharging a gate line 01 connected by the output terminal of the discharging module when the gate line 01 connected by the control terminal of the discharging module is applied with a scanning signal by the shift register unit 02.

Specifically, in the above display panel provided by the embodiment of the present invention, in order to implement the function of line by line scanning and frame by frame refreshing of the display panel, and enable the image data inputted into the display panel to be refreshed in real time, so as to realize dynamic display, it should also be ensured that the previous row of gate line 01 of the charged gate line 01 is in the off state at the same time of increasing the charging rate of the gate line. Hence, except for the first row of gate line 01, discharging modules 04 in one-to-one correspondence with respective gate lines 01 are further arranged at the other terminal of the other gate lines 01, when the gate line 01 is applied with a scanning signal by a corresponding shift register unit 02, the discharging module 04 to which the gate line 01 corresponds discharges a previous row of gate line 01 adjacent to the gate line 01 at the same time, leads out the residual charges of the adjacent previous row of gate line 01, thereby ensuring that the previous row of gate line 01 is in the off state, and avoiding it from influencing the process of realizing line by line scanning of the display panel.

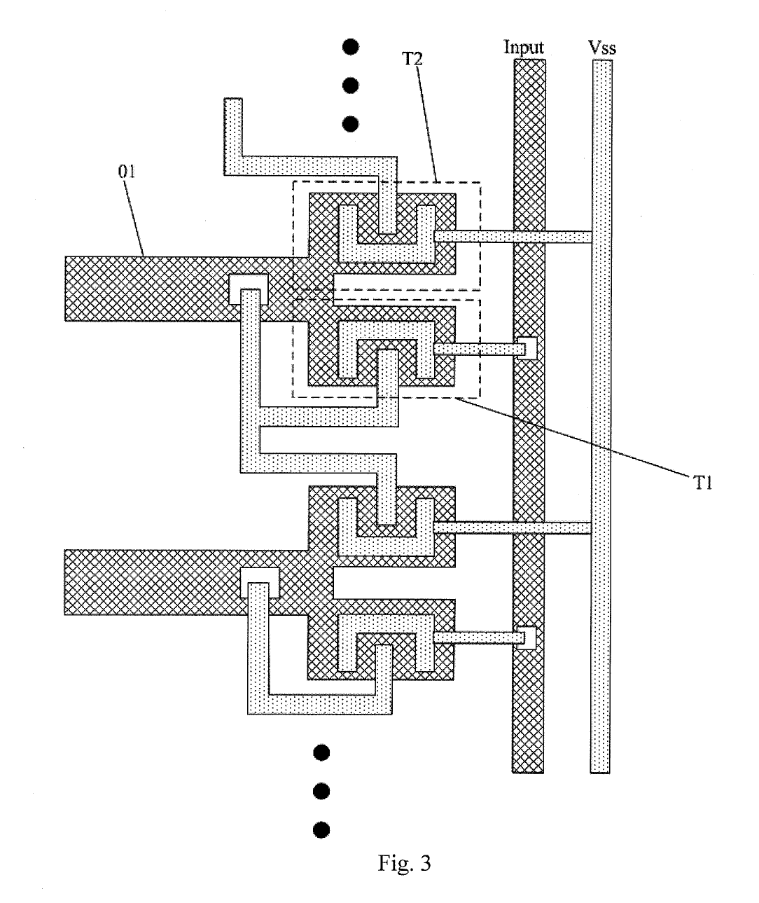

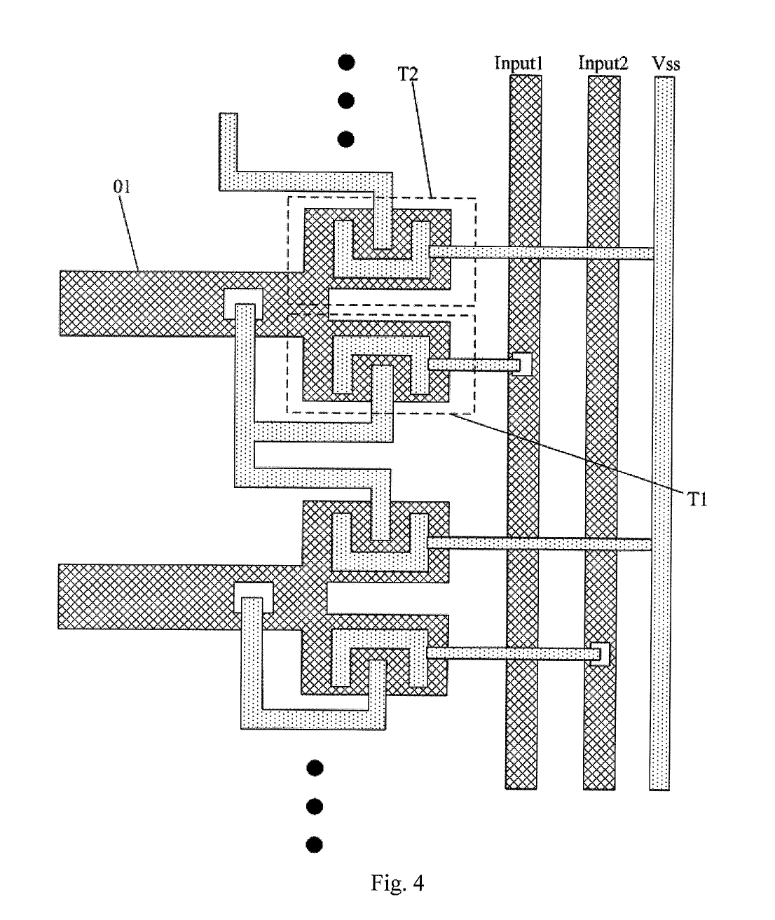

In specific implementation, in the above display panel provided by the embodiment of the present invention, the charging module 03, as shown in FIG. 3 and FIG. 4, may specifically comprise a first switch transistor T1. The gate and the drain of the first switch transistor T1 are connected with the gate line 01 respectively. The source of the first switch transistor T1 is connected with the signal input line Input.

Specifically, in the above display panel provided by the embodiment of the present invention, the charging module 03 may be constituted by the first switch transistor T1. Since the scanning signal applied in the gate line 01 is used for controlling the switch transistors as switches in the respective pixel units to turn on. This thereby enables respective pixel units to realize image display, whereas when each shift register unit 02 applies a scanning signal to a corresponding gate line 01, the scanning signal applied in the gate line 01 will also control the first switch transistor T1 to turn on, such that the signal in the signal input line is applied to the gate line 01. Implementing the function of bidirectional application of the scanning signal to the gate line 01, and increasing the charging rate of the gate line 01, therefore, the transistor type of the first switch transistor T1 has to be consistent with the type of the switch transistors in the respective pixel units connected by the gate line 01. When the switch transistor in the pixel unit is a N-type transistor, the first switch transistor T1 is a N-type transistor. When the switch transistor in the pixel unit is a P-type transistor, the first switch transistor T1 is a P-type transistor.

Specifically, in the above display panel provided by the embodiment of the present invention, in order to realize bidirectional application to the gate line 01, and increase the charging rate of the gate line 01, the signal inputted by the signal input line Input is the same as the scanning signal applied by the respective shift register units 02 to the gate line 01. The scanning signal applied to the gate line 01 controls the on and off state of the first switch transistor T 1. Hence, when the corresponding first switch transistor T1 is a transistor of the same type, the signal input line Input will input a scanning signal that corresponds to the transistor of the same type accordingly. For example, if the first switch transistor T1 is a N-type transistor, when the gate line 01 is applied with a high level scanning signal by the shift register unit 02, the scanning signal on the gate line 01 controls the corresponding first switch transistor T1 to be in the turn-on state. The turned-on first switch transistor T1 transfers the high level signal on the signal input line Input to the gate line 01, to realize bidirectional application of the scanning signal to the gate line 01 and increase the charging rate of the gate line 01.

In some implementations, in the above display panel provided by the embodiment of the present invention, the discharging module 04, as shown in FIG. 3 and FIG. 4, may specifically comprise: a second switch transistor T2; the gate of the second switch transistor T2 is connected with a corresponding gate line 01, the source of the second switch transistor T2 is connected with a low level signal line Vss, the drain of the second switch transistor T2 is connected with a previous row of gate line adjacent to the corresponding gate line.

Specifically, in the above display panel provided by the embodiment of the present invention, the discharging module 04 may be constituted by the second switch transistor T2, since the scanning signal applied in the gate line 01 is used for controlling the switch transistors as switches in the respective pixel units to turn on, thereby enabling respective pixel units to realize image display. When each shift register unit 02 applies a scanning signal to a corresponding gate line 01, the scanning signal applied in the gate line 01 will also control the second switch transistor T2 to turn on, such that the signal on the low level signal line Vss is transferred to a previous row of gate line 01 adjacent to the corresponding gate line 01, i.e., discharging the adjacent previous row of gate line 01. This enables it to be in the off state, therefore, the transistor type of the second switch transistor T2 has to be consistent with the type of the switch transistor in the pixel unit connected by the gate line 01. When the switch transistor in the pixel unit is a N-type transistor, the second switch transistor T2 is a N-type transistor. When the switch transistor in the pixel unit is a P-type transistor, the second switch transistor T2 is a P-type transistor.

Specifically, in the above display panel provided by the embodiment of the present invention, in order to realize that when the corresponding gate line 01 is applied with a scanning signal, the previous row of gate line 01 adjacent to it is in the off state, i.e., ensuring line by line scanning process of the gate lines 01 on the display panel. The signal inputted on the low level signal line Vss and the scanning signal applied by the respective shift register units 02 to the gate line 01 have opposite polarities, whereas the scanning signal applied on the gate line 01 is used for controlling the turn-on state of the second switch transistor T2. Hence, when the corresponding second switch transistor T2 is a transistor of the same type, the low level signal line Vss will input a control signal contrary to the signal for controlling the transistor of the same type to turn on correspondingly. Specifically, for example, if second switch transistor T2 is a N-type transistor, when the gate line 01 is applied with a high level scanning signal by the shift register unit 02, the scanning signal on the gate line 01 controls the corresponding second switch transistor T2 to be in the turn-on state. The turned-on second switch transistor T2 transfers the low level signal on the low level signal line Vss to a previous row of gate line 01 adjacent to the gate line 01, i.e., providing a signal for pulling down the voltage for the adjacent previous row of gate line 01, and ensuring the previous row of gate line 01 to be in the off state, so as to avoid the half-off state of the previous row of gate line 01, which may result in the problem of influencing line by line scanning of the display panel.

It should be noted that the switch transistor mentioned in the above embodiment of the present invention may be a thin film transistor (TFT), and may also be a metal oxide semiconductor (MOS) field effect transistor, which will not be defined here. In specific implementation, the source and the drain of these transistors can be interchanged, which will not be differentiated specifically. In describing the specific embodiments, the thin film transistor is taken as the example for explanation.

In some implementations, in the above display panel provided by the embodiment of the present invention, as shown in FIG. 3, the number of the signal input line Input may be one and the signal inputted by the signal input line Input may be a DC signal. In this way, when the first switch transistor T1 that constitutes the charging module 03 is in the turn-on state, the turned-on first switch transistor T1 transfers the DC signal inputted on the signal input line Input to the corresponding gate line 01, and charges the gate line 01 simultaneously with the shift register unit 02, so as to realize bidirectional application of the scanning signal to the gate line 01 and increase the charging rate of the gate line 01.

In some implementations, in the above display panel provided by the embodiment of the present invention, as shown in FIG. 4, the number of the signal input line Input may also be two, i.e., the signal input line Input may comprise a first signal input line Input1 and a second signal input line Input2. The signals inputted by the two signal input lines may have opposite polarities at the same moment; any two adjacent charging modules 03 in the plurality of charging modules are connected with different signal input lines respectively. In this way, by arranging the first signal input line Input1 and the second signal input line Input2, the load of a single signal input line Input can be reduced. Moreover, the first signal input line Input 1 and the second signal input line Input2 input complementary pulse signals at the same moment. Thus, when the Nth row of gate line 01 is charged, the signal in the signal input line that inputs a signal to the Nth row of gate line 01 is a scanning signal, the signal in the signal input line that inputs a signal to the N−1 th row of gate line 01 is a signal that has a polarity opposite to the scanning signal, thus it can further avoid half-off state of the previous row of gate line adjacent to the charged gate line 01.

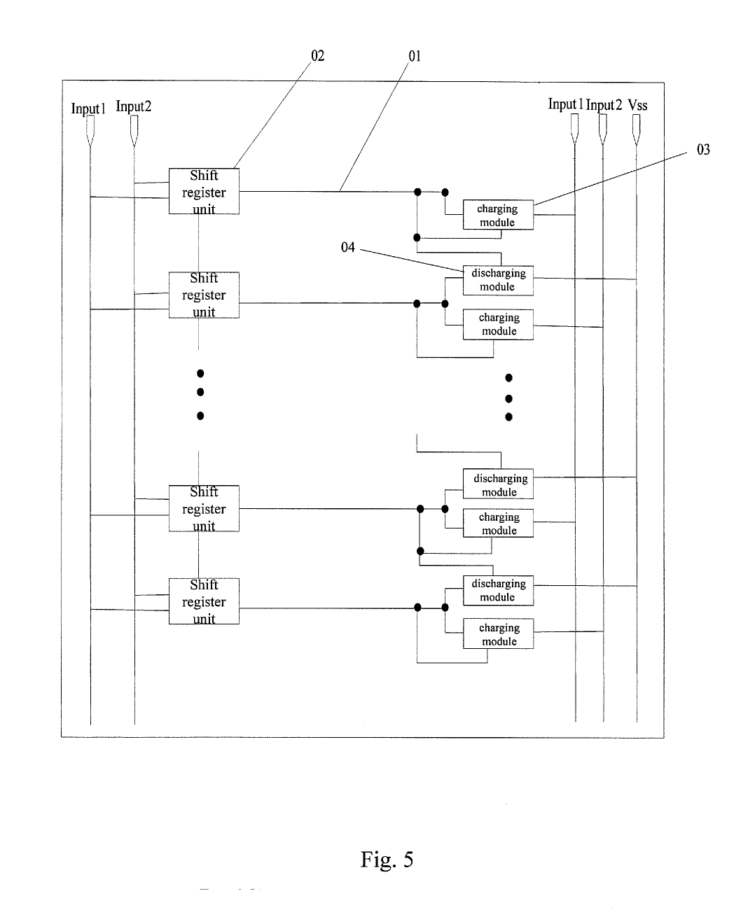

In some implementations, as shown in FIG. 5, each shift register unit 02 may have two signal input terminals, signals inputted by the two signal input terminals are the same as the signals inputted by the two signal input lines (i.e., the first signal input line Input1 and the second signal input line Input2) respectively, i.e., the shift register unit 02 outputs signals at every moment, it outputs a scanning signal to the gate line 01 at the moment of charging the gate line 01, and outputs a signal having a polarity opposite to the scanning signal to the gate line 01 when the gate line 01 is in the off state. In this way, by corresponding to the scanning state of the gate line 01 and cooperating with the working time sequence of the charging module 03 and the discharging module 04, the charging rate of the gate line 01 can be enhanced, and the half-off state of the gate line 01 can be further avoided, thereby avoiding the problem of influencing line by line scanning of the display panel due to half-off state of the gate line 01.

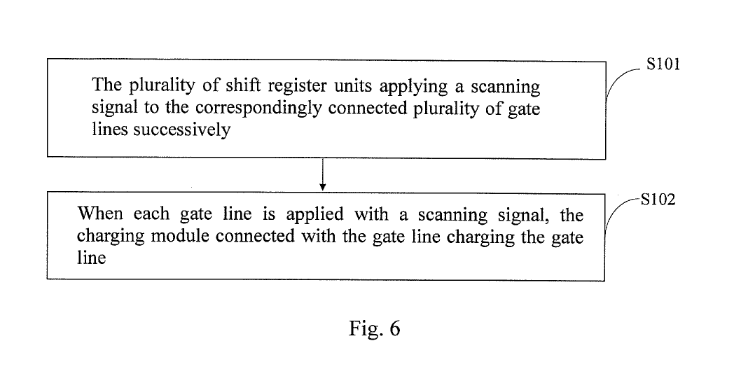

Based on the same inventive concept, an embodiment of a method of driving the above display panel is provided in FIG. 6. It may specifically comprise the steps of:

S101. The plurality of shift register units apply a scanning signal to the correspondingly connected plurality of gate lines successively. Specifically, the gate integrated driving circuit controls the display panel to implement the functions of line by line scanning and frame by frame refreshing, such that the image data inputted into the display panel can be refreshed in real time, thereby realizing dynamic display. Wherein the respective shift register units in the gate integrated driving circuit generate gate line scanning signals opened line by line with respect to time sequence control; control the pixel switch to be turned on after applying each row of gate line scanning signal to the corresponding gate line, such that the image data enters the storage capacitance of this row of pixel, so as to realize normal display of images finally.

S102. When each gate line is applied with a scanning signal, the charging module connected with the gate line charges the gate line. Specifically, in the method of driving the above display panel provided by the embodiment of the present invention, in the process of line by line scanning of the display panel, the respective shift register units apply scanning signals to the correspondingly connected gate lines based on the time sequence control, whereas when the respective gate lines are applied with the scanning signals, the charging modules connected with the gate lines charge the gate lines simultaneously, thus bidirectional application of the scanning signal to the gate line can be realized, so as to increase the charging rate of the gate line.

In some implementations, the method of driving the above display panel provided by the embodiment of the present invention may further comprise: when each gate line in the plurality of gate lines except for the first row of gate line is applied with a scanning signal, the discharging module connected with the gate line discharges a previous row of gate line adjacent to the gate line.

Specifically, in the method of driving the above display panel provided by the embodiment of the present invention, in the process of line by line scanning of the display panel, when respective gate lines except for the first row of gate line are applied with the scanning signals, the discharging module connected with the gate line can discharge the previous row of gate line adjacent to the gate line. Thus, the residual charges on the previous row of gate line adjacent to the gate line can be led out, so as to ensure that the previous row of gate line is in the off state, and avoid it from influencing the line by line scanning process of the display panel.

Based on the same inventive concept, the embodiment of the present invention provides a display device comprising the above display panel provided by the embodiment of the present invention. The display device may be applied in any products or components with the display function such as mobile phones, tablet computers, televisions, displays, laptops, digital photo frames, navigators etc. Since the display device has a similar principle for solving problems as the display panel, the implementation of the display device may refer to the implementation of the above display panel, which will not be repeated.

The embodiments of the present invention provide a display panel, a driving method thereof and a display device, the display panel comprising a plurality of gate lines, and a plurality of shift register units connected with one terminal of the plurality of gate lines respectively in one-to-one correspondence, the display panel further comprising a plurality of charging modules connected with the other terminal of the plurality of gate lines respectively in one-to-one correspondence; a control terminal and an output terminal of each charging module are connected with a corresponding gate line respectively, an input terminal of each charging module is connected with a signal input line; each charging module is used for charging a gate line connected by the output terminal of the charging module when the gate line connected by the control terminal of the charging module is applied with a scanning signal by the shift register unit. In this way, by arranging shift register units in one-to-one correspondence with the gate lines at one terminal of the gate lines in the display panel, meanwhile arranging charging modules in one-to-one correspondence with the gate lines at the other terminal of the gate lines, when the shift register unit applies a scanning signal to the gate line, the charging module to which the gate line corresponds charges the gate line at the same time, i.e., the gate line is also applied with the scanning signal, thereby the gate line can be applied with the scanning signal bidirectionally, which increases the charging rate of the gate line. Compared with the manner of expanding the areas occupied by respective shift register units or using the bilaterally arranged gate integrated driving circuit for bilateral driving in order to increase the charging rate of the gate line in the prior art, the display panel provided by the embodiment of the present invention only uses the unilaterally arranged gate integrated driving circuit, and the areas occupied by the respective shift register units in the gate integrated driving circuit do not have to be expanded, which ensures narrow frame design of the display panel, thereby increasing the charging rate of the gate line while keeping narrow frame design of the display panel.

Apparently, the skilled person in the art can make various modifications and variants to the respective embodiments according to the present invention without departing from the spirit and scope of the present invention. In this way, provided that these modifications and variants belong to the scopes of the claims of the present invention and the equivalent technologies thereof, the present invention would also intend to cover these modifications and variants.

1. A display panel comprising: a plurality of gate lines, and a plurality of shift register units connected with one terminal of the plurality of gate lines respectively in one-to-one correspondence,
wherein the display panel further comprises a plurality of charging modules connected with the other terminal of the plurality of gate lines respectively in one-to-one correspondence, a control terminal and an output terminal of each charging module are connected with a corresponding gate line respectively, an input terminal of each charging module is connected with a signal input line, and
wherein each charging module is used for charging a gate line connected by the output terminal of the charging module when the gate line connected by the control terminal of the charging module is applied with a scanning signal by the shift register unit.

2. The display panel as claimed in claim 1, wherein the charging module comprises a first switch transistor, wherein a gate and a drain of the first switch transistor are connected with the gate line respectively, a source of the first switch transistor is connected with the signal input line.

3. The display panel as claimed in claim 1, further comprising a plurality of discharging modules connected with the other terminal of the gate lines except for the first row of gate line in the plurality of gate lines respectively in one-to-one correspondence;
wherein a control terminal of each discharging module is connected with a corresponding gate line, an input terminal of each discharging module is connected with a low level signal line, and an output terminal of each discharging module is connected with a previous row of gate line adjacent to the corresponding gate line; and
wherein each discharging module is used for discharging a gate line connected by the output terminal of the discharging module when the gate line connected by the control terminal of the discharging module is applied with a scanning signal by the shift register unit.

4. The display panel as claimed in claim 3, wherein the discharging module comprises a second switch transistor; and wherein
a gate of the second switch transistor is connected with a corresponding gate line, a source of the second switch transistor is connected with the low level signal line, a drain of the second switch transistor is connected with a previous row of gate line adjacent to the corresponding gate line.

5. The display panel as claimed in claim 1, wherein the number of the signal input line is one, and the signal inputted by the signal input line is a DC signal.

6. The display device as claimed in claim 1, wherein the number of the signal input lines is two, and signals inputted by the two signal input lines have opposite polarities at the same moment;
wherein any two adjacent charging modules in the plurality of charging modules are connected with different signal input lines respectively.

7. The display panel as claimed in claim 6, wherein each shift register unit has two signal input terminals, and wherein signals inputted by the two signal input terminals are the same as the signals inputted by the two signal input lines respectively.

8. A method of driving a display panel, the display panel comprising a plurality of gate lines, a plurality of shift register units connected with one terminal of the plurality of gate lines respectively in one-to-one correspondence, and a plurality of charging modules connected with the other terminal of the plurality of gate lines respectively in one-to-one correspondence, a control terminal and an output terminal of each charging module being connected with a corresponding gate line respectively, an input terminal of each charging module being connected with a signal input line, the method comprising:
Applying, by the plurality of shift register units, a scanning signal to the correspondingly connected plurality of gate lines successively;
when each gate line is applied with a scanning signal, charging the gate line via the charging module connected with the gate line.

9. The method as claimed in claim 8, further comprising:
Discharging, by the discharging module connected with the gate line, a previous row of gate line adjacent to the gate line when each gate line in the plurality of gate lines except for the first row of gate line is applied with a scanning signal.

10. A display device comprising a display panel, the display panel comprising: a plurality of gate lines, and a plurality of shift register units connected with one terminal of the plurality of gate lines respectively in one-to-one correspondence,
wherein the display panel further comprises a plurality of charging modules connected with the other terminal of the plurality of gate lines respectively in one-to-one correspondence, a control terminal and an output terminal of each charging module are connected with a corresponding gate line respectively, an input terminal of each charging module is connected with a signal input line, and
each charging module is used for charging a gate line connected by the output terminal of the charging module when the gate line connected by the control terminal of the charging module is applied with a scanning signal by the shift register unit.

11. The display device as claim in claim 10, wherein the charging module comprises a first switch transistor; and
wherein a gate and a drain of the first switch transistor are connected with the gate line respectively, a source of the first switch transistor is connected with the signal input line.

12. The display device as claimed in claim 10, further comprising a plurality of discharging modules connected with the other terminal of the gate lines except for the first row of gate line in the plurality of gate lines respectively in one-to-one correspondence;
wherein a control terminal of each discharging module is connected with a corresponding gate line, an input terminal of each discharging module is connected with a low level signal line, an output terminal of each discharging module is connected with a previous row of gate line adjacent to the corresponding gate line; and
wherein each discharging module is used for discharging a gate line connected by the output terminal of the discharging module when the gate line connected by the control terminal of the discharging module is applied with a scanning signal by the shift register unit.

13. The display device as claimed in claim 12, wherein the discharging module comprises a second switch transistor;
wherein a gate of the second switch transistor is connected with a corresponding gate line, a source of the second switch transistor is connected with the low level signal line, a drain of the second switch transistor is connected with a previous row of gate line adjacent to the corresponding gate line.

14. The display device as claimed in claim 10, wherein the number of the signal input line is one, and the signal inputted by the signal input line is a DC signal.

15. The display device as claimed in claim 10, wherein the number of the signal input lines is two, and signals inputted by the two signal input lines have opposite polarities at the same moment;
wherein any two adjacent charging modules in the plurality of charging modules are connected with different signal input lines respectively.

16. The display device as claimed in claim 15, wherein each shift register unit has two signal input terminals, signals inputted by the two signal input terminals are the same as the signals inputted by the two signal input lines respectively.
